(19) United States
(12) Patent Application Publication
(10) Pub. No.: US 2019/0309420 A1
(43) Pub. Date: Oct. 10, 2019

(54) Substrate Processing Apparatus and Substrate Processing Method

(71) Applicant: TOKYO ELECTRON LIMITED, Tokyo (JP)

(72) Inventors: Masami OIKAWA, Oshu City (JP); Ken ITABASHI, Nirasaki City (JP); Satoshi TAKAGI, Nirasaki City (JP); Masahisa WATANABE, Nirasaki City (JP); Keisuke FUJITA, Nirasaki City (JP); Tatsuya MIYAHARA, Nirasaki City (JP); Hiroyuki HAYASHI, Nirasaki City (JP)

(21) Appl. No.: 16/371,818

(22) Filed: Apr. 1, 2019

(30) Foreign Application Priority Data
Apr. 6, 2018 (JP) 2018-073876

(51) Int. Cl. C23C 16/455; H01L 21/673; H01L 21/02; H01L 21/311; C23C 16/52

(52) U.S. Cl. CPC C23C 16/45578; H01L 21/67303; C23C 16/52; H01L 21/31105; C23C 16/45574; H01L 21/02532

(57) ABSTRACT

There is provided a substrate processing apparatus including: a processing container accommodating a boat on which a substrate is mounted; and an injector that extends in a vertical direction along an inner wall of the processing container in a vicinity of the processing container and has a plurality of gas holes in a longitudinal direction, wherein the plurality of gas holes is oriented toward the inner wall in the vicinity of the processing container.

### CROSS-REFERENCE TO RELATED APPLICATION

This application is based upon and claims the benefit of priority from Japanese Patent Application No. 2018-073876, filed on Apr. 6, 2018, the entire contents of which are incorporated herein by reference.

### TECHNICAL FIELD

The present disclosure relates to a substrate processing apparatus and a substrate processing method.

### BACKGROUND

A heat treatment apparatus including a gas nozzle (injector) was proposed that extends along a lateral side of a substrate and has gas holes formed intermittently in a longitudinal direction in a processing container. In this proposed heat treatment apparatus, with reference to a center line connecting the center of the gas nozzle and the center of the substrate, an orientation angle θ of the gas holes is set to a range of an angle or more, the angle being between a reference line (the aforementioned center line) and a tangent line connecting the outer peripheral end portion of the substrate and the center of the gas nozzle.

A reaction apparatus has also been proposed in which a plurality of gas ejection ports provided in a longitudinal direction of an injector are facing a direction different from a direction toward the center of a substrate placed on a support, for example, facing 90 degrees with respect to the center direction of the substrate.

However, the above-mentioned heat treatment apparatus and reaction apparatus have room for improvement in the in-plane uniformity of a silicon film formed on the substrate. In an apparatus in which gas ejection ports are oriented to a direction of 90 degrees with respect to the center direction of the substrate as in the above-mentioned reaction apparatus, when a plurality of injectors is arranged at intervals on the inner side of the inner wall of a processing container, a gas discharged 90 degrees from a gas ejection port of one of the injectors directly collides with other adjacent injectors, which makes it difficult to spread the gas into the processing container.

### SUMMARY

Some embodiments of the present disclosure provide a substrate processing apparatus and a substrate processing method capable of forming a silicon film having good in-plane uniformity and inter-plane uniformity on a substrate.

According to one embodiment of the present disclosure, there is provided a substrate processing apparatus including: a processing container accommodating a boat on which a substrate is mounted; and an injector that extends in a vertical direction along an inner wall of the processing container in a vicinity of the processing container and has a plurality of gas holes in a longitudinal direction, wherein the plurality of gas holes is oriented toward the inner wall in the vicinity of the processing container.

According to another embodiment of the present disclosure, there is provided a method of processing a substrate in a processing container in which a boat on which the substrate is mounted is accommodated, the method including: supplying a process gas from a plurality of gas holes of an injector that extends in a vertical direction along an inner wall of the processing container in a vicinity of the processing container, wherein the process gas is discharged toward the inner wall in a vicinity of the injector from the plurality of gas holes of the injector, reflected by the inner wall, and then diffused into the processing container to process the substrate.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a sectional view showing an exemplary embodiment of the overall configuration of a substrate processing system including a substrate processing apparatus according to an embodiment of the present disclosure.

FIG. 2 is a sectional view taken along arrow II-II in FIG. 1 and cut along a horizontal plane passing through a gas hole of the longest injector.

FIG. 3 is a sectional view taken along arrow in FIG. 1 and cut along a horizontal plane passing through a gas hole of the medium length injector.

FIG. 4 is a sectional view taken along arrow IV-IV in FIG. 1 and cut along a horizontal plane passing through a gas hole of the shortest injector.

FIG. 5 is a view showing an exemplary embodiment of a hardware configuration of a controller constituting the substrate processing system.

FIG. 6 is a view showing an exemplary embodiment of a functional configuration of the controller constituting the substrate processing system.

FIGS. 7A to 7F are a cross-sectional process view for explaining an example of a substrate processing method according to an embodiment of the present disclosure.

FIG. 8 is a view showing results of analysis on the etching gas concentration and results of experiments on the etching amount according to Comparative Example 1 in which an etching gas is flown in the wafer center direction and Example 1 in which the etching gas is flown in the tube direction (direction opposite to the wafer center).

FIG. 9A is a view showing the results of an experiment on the etching amount in Comparative Example 1 in the center area of a wafer boat.

FIG. 9B is a view showing the results of an experiment on in-plane uniformity in Comparative Example 1.

FIG. 10A is a view showing the results of an experiment on the etching amount in Comparative Example 1 in the center area of the wafer boat.

FIG. 10B is a view showing the results of an experiment on in-plane uniformity in Example 1.

FIG. 11A is a view showing the results of an experiment on the film thickness and the in-plane film thickness uniformity in Comparative Example 2 ranging from the lower region to the upper region of the wafer boat.

FIG. 11B is a view showing the results of an experiment on the film thickness and the in-plane film thickness uniformity in Example 2 ranging from the lower region to the upper region of the wafer boat.

FIG. 12 is a view showing the results of an airflow analysis showing the flow velocity distribution of a precursor gas when the discharge direction of the precursor gas is changed in the upper region of the processing container.

FIG. 13 is a view showing the results of an airflow analysis showing the flow velocity distribution of the precursor gas when the discharge direction of the precursor gas is changed in the central region of the processing container.

FIG. 14 is a view showing the results of an airflow analysis showing the flow velocity distribution of the precursor gas when the discharge direction of the precursor gas is changed in the lower region of the processing container.

FIG. 15 is a view showing the results of an airflow analysis showing a streamline of the precursor gas in the vicinity of an injector.

FIG. 16 is a view showing the results of an airflow analysis showing a streamline of the precursor gas from an injector to a wafer.

### DETAILED DESCRIPTION

Reference will now be made in detail to a substrate processing apparatus, a substrate processing system including the substrate processing apparatus, and a substrate processing method according to various embodiments, examples of which are illustrated in the accompanying drawings. Throughout the present disclosure and the drawings, substantially the same elements are denoted by the same reference numerals and therefore, explanation thereof will not be repeated. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### EMBODIMENTS

### <Substrate Processing System>

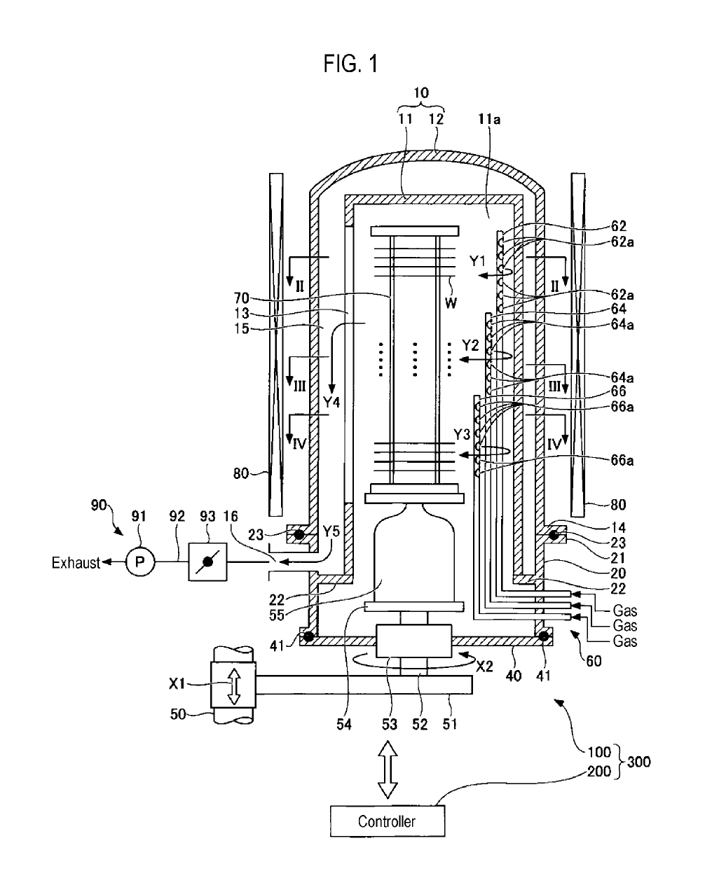

First, the overall configuration of a substrate processing system including a substrate processing apparatus according to an embodiment of the present disclosure will be outlined. FIG. 1 is a sectional view showing an exemplary embodiment of the overall configuration of a substrate processing system according to an embodiment of the present disclosure.

As shown in FIG. 1, the substrate processing system 300 includes a substrate processing apparatus 100 which is a batch type vertical film forming apparatus, and a controller 200. The controller 200 is connected, wired or wireless, to respective parts constituting the substrate processing apparatus 100 and transmits command signals based on various process recipes stored in the controller 200 to the respective parts of the substrate processing apparatus 100, so that film formation on a substrate by the substrate processing apparatus 100 is executed. Various kinds of sensor information and the like constituting the substrate processing apparatus 100 are transmitted to the controller 200. The controller 200 continues/stops various processes, changes the temperature conditions, the pressure conditions and the like in the substrate processing apparatus 100, based on the received sensor information and the like.

### <Substrate Processing Apparatus>

Next, a substrate processing apparatus according to an embodiment of the present disclosure will be described with reference to FIG. 1. The substrate processing apparatus 100 includes a processing container 10, a heater 80 surrounding the processing container 10 outside the processing container 10, a gas supply part 60 for supplying various gases into the processing container 10, and a gas exhaust part 90 for exhausting gases from the processing container 10. The substrate processing apparatus 100 further includes a wafer boat 70 that holds a plurality of semiconductor wafers (hereinafter referred simply to as “wafers”), which are substrates, in a vertical direction at predetermined intervals, and a boat elevator 50 that loads/unloads the plurality of wafers into/from the processing container 10 by raising/lowering the wafer boat 70 in the X1 direction.

The processing container 10 has a cylindrical inner tube 11 (inner processing tube) its lower end opened and having a ceiling, and a cylindrical outer tube 12 (outer processing tube) with its lower end opened and having a ceiling that covers the outer side of the inner tube 11. Both the inner tube 11 and the outer tube 12 are made of a heat resistant material such as quartz, and are arranged coaxially to form a double tube structure.

In one embodiment, the ceiling of the inner tube 11 may be flat. An injector arrangement region 11a in which an injector is disposed is formed in one region on the inner side of the inner wall surface of the cylindrical inner tube 11, and a gas exhaust port 13 for exhausting gases out of the inner tube 11 is formed in the other region opposed to the injector arrangement region 11a. The gas exhaust port 13 is an exhaust port for mainly exhausting a process gas in the inner tube 11, and its length in the vertical direction can be appropriately set. Therefore, for example, as illustrated in the figure, the gas exhaust port 13 may have an opening having substantially the same length in the vertical direction of the wafer boat 70.

The lower end of each of the inner tube 11 and the outer tube 12 forming the processing container 10 is supported by a cylindrical manifold 20 made of, for example, stainless steel. An annular flange 21 for supporting the outer tube 12 is formed on the upper end of the cylindrical manifold 20 so as to protrude outward. Further, an annular flange 22 for supporting the inner tube 11 is formed in the lower side of the manifold 20 so as to protrude inward. The lower end of the inner tube 11 is placed on and supported by the annular flange 22, and an annular flange 14 of the lower end of the outer tube 12 is placed on and supported by the annular flange 21. A seal member 23 such as an O-ring is interposed between the annular flange 21 of the manifold 20 and the annular flange 14 of the outer tube 12, and the outer tube 12 and the manifold 20 are connected via the seal member 23 in an air-tight manner.

A lid 40 is attached to the lower end opening of the cylindrical manifold 20 in an air-tight manner via a seal member 41 such as an O-ring so as to air-tightly close the lower end opening of the processing container 10. The lid 40 may be made of stainless steel.

A magnetic fluid seal member 53 is attached to the central portion of the lid 40, and a rotary shaft 52 is rotatable and penetrates through (loosely fits in) this magnetic fluid seal member 53 in an airtight state. The lower end of the rotary shaft 52 is rotatably supported by a support arm 51 extending laterally from the boat elevator 50, which is an elevating mechanism, and is rotatable in the X2 direction by an actuator such as a motor or the like.

A rotating plate 54 is disposed at the upper end of the rotary shaft 52, and a heat insulating barrel 55 made of quartz is mounted on the rotating plate 54. The wafer boat 70 for holding a plurality of wafers W aligned at predetermined intervals in the vertical direction is placed on the heat insulating barrel 55. In this configuration, when the boat elevator 50 is raised/lowered in the X1 direction, the wafer boat 70 ascends/descends integrally via the support arm 51, the rotating plate 54 and the heat insulating barrel 55 so as to be loaded/unloaded into/from the processing container 10. Further, the wafer boat 70 may be rotated by the rotation of the rotary shaft 52.

The gas supply part 60 includes a plurality of gas supply sources (not shown) and a plurality of injectors (for example, three injectors as illustrated) 62, 64 and 66 in fluid communication with the plurality of gas supply sources via a control valve (not shown). The respective injectors 62, 64 and 66 are disposed along the longitudinal direction (vertical direction) of the inner tube 11 on the inner side of the inner wall of the inner tube 11, and their base ends are bent in an L shape and extends to the corresponding gas supply through the side of the manifold 20.

The injectors 62, 64 and 66 are arranged at intervals so as to be aligned in the circumferential direction in the injector arrangement region 11a on the inner side of the inner wall of the inner tube 11. The injectors 62, 64 and 66 have a shorter length in the vertical direction in this order.

In order to supply a process gas to the upper region of the inner tube 11, a plurality of gas holes 62a is opened and formed in the longest injector 62 at predetermined intervals along the longitudinal direction within a predetermined range of upper portion of the injector 62. The plurality of gas holes 62a is oriented toward the inner wall side in the vicinity of the inner tube 11. Then, after various process gases discharged horizontally, through the gas holes 62a oriented toward the inner wall side in the vicinity of the inner tube 11, are reflected by the inner wall surface, these gases can be supplied to the wafer W side in the Y1 direction.

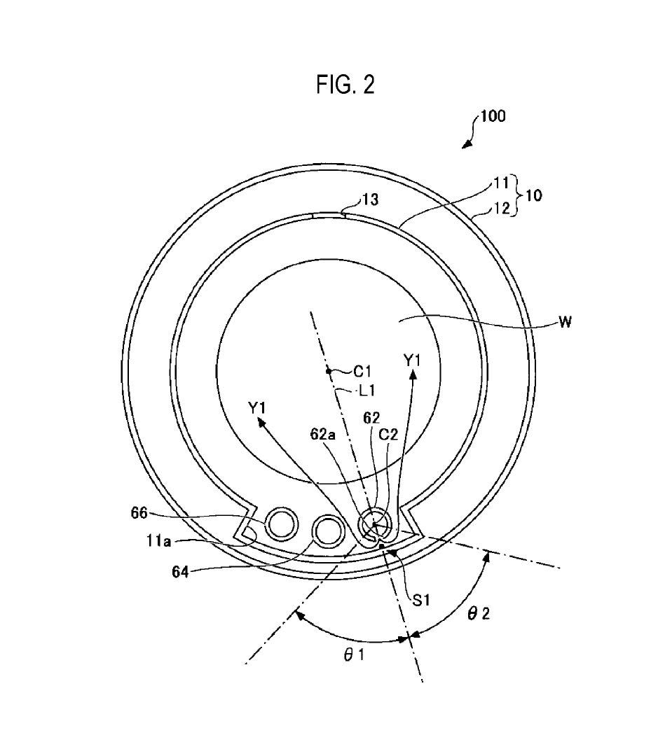

The orientation angle of the gas hole 62a will be described with reference to FIG. 2. FIG. 2 is a sectional view taken along arrow II-II in FIG. 1 and cut along a horizontal plane passing through a gas hole of the longest injector (a plan view of the substrate processing apparatus).

As shown in FIG. 2, a point where a radial line L1 passing through the center C1 of a wafer W mounted on the wafer boat and the center C2 of the injector 62 intersects the inner wall of the inner tube 11 in the plan view of the substrate processing apparatus 100 is referred to a reference point S1. An angular range from the reference point S1 around the axis center passing through the center C2 of the injector 62 is a range of clockwise angle θ1 and counterclockwise angle θ2, each of which is 60 degrees or less, to which the gas hole 62a is oriented. That is, the gas hole 62a is oriented toward the inner tube 11 side within a range of 120 degrees around the reference point S1.

In this way, since the gas hole 62a is oriented within the range of 120 degrees around the reference point S1, various process gases discharged from the gas hole 62a of the injector 62 can be first reflected by the inner wall of the inner tube 11 and then diffused in the Y1 direction toward the wafer W side. In addition, the various process gases discharged from the gas hole 62a of the injector 62 can be first reflected by the inner wall of the inner tube 11, reflected by the injector 62 and then diffused in the Y1 direction toward the wafer W side. Further, the various process gases discharged from the gas hole 62a of the injector 62 can be first reflected by the inner wall of the inner tube 11, reflected by an adjacent injector 64, additionally reflected by the injector 62 in some cases, and then diffused in the Y1 direction toward the wafer W side. Like an injector constituting the conventional substrate processing apparatus, in a form in which a gas hole is oriented to the wafer side (as can be confirmed from the results of analysis and experiments conducted by the present inventors, which will be described later), the etching amount in a region close to the gas hole becomes relatively small, which makes it difficult to form a silicon film having in-plane film thickness uniformity on the wafer surface. The various process gases discharged from the gas hole 62a are reflected by the inner wall of the inner tube 11 and then reflected by the injector 62 and further to the adjacent injector 64, so that the multi-reflected process gases diffuse not only in the horizontal direction but also in the vertical direction into the processing container 10.

In a process of supplying a process gas into the inner tube 11 with its interior set to a predetermined high temperature, due to a flow of the process gas in the Y1 direction in which the process gas collides against and is reflected by the inner wall of the inner tube 11 and diffused toward the wafer W side as shown in FIG. 2, it is possible to prolong the time taken until the process gas reaches the wafer W. As a result, the temperature of the process gas tends to rise to a predetermined temperature in the course of reaching the wafer W and the process gas tends to be provided to the wafer W in a decomposed state due to the rise in temperature. Therefore, a sufficient action by the decomposed process gas is exerted. Specifically, when the process gas is an etching gas such as a chlorine (Cl₂) gas, a high etching effect is achieved by the chlorine gas that is decomposed by raising the temperature. When the process gas is a precursor gas such as a disilane (Si₂H₆) gas, good film attachment (reduction of incubation time) is achieved by the disilane gas decomposed by raising the temperature. On the other hand, as in the conventional injector, in the case where the process gas is directly discharged to the wafer W, the process gas reaches the wafer W before it is decomposed by raising the temperature, which makes it difficult to achieve the expected action of various process gases with satisfaction.

As described above, in one embodiment, the orientation angle range of the gas hole 62a of the injector 62 is an angular range of 60 degrees or less in each of the clockwise and the counterclockwise direction from the reference point 51. However, it is more preferable that the orientation angle range is an angular range of 45 degrees or less in each of the clockwise and the counterclockwise direction. That is, it is preferable to orient the gas hole 62a toward the inner tube 11 side in the range of 90 degrees around the reference point S1. In this angular range, the process gas discharged from the gas hole 62a collides against and is reflected by the inner wall of the inner tube 11 with a stronger impact force. As a result, the turbulent state of the process gas is further promoted, the time required for the process gas to reach the wafer W is further lengthened, and a more even amount of process gas can be supplied onto the entire surface of the wafer W.

On the other hand, in another embodiment, in order to supply a process gas to the central region of the inner tube 11, a plurality of gas holes 64a is opened and formed in the medium length injector 64 at predetermined intervals along the longitudinal direction within a predetermined range of upper portion of the injector 64 and are oriented toward the inner wall side in the vicinity of the inner tube 11, such as like the injector 62. Then, various process gases discharged horizontally through the gas holes 64a oriented toward the inner wall side in the vicinity of the inner tube 11 can be first reflected by the inner wall surface and then supplied to the wafer W side in the Y2 direction. In addition, the various process gases discharged from the gas holes 64a of the injector 64 can be first reflected by the inner wall of the inner tube 11, reflected by the injector 64 and then diffused in the Y2 direction toward the wafer W side. Further, the various process gases discharged from the gas holes 64a of the injector 64 can be first reflected by the inner wall of the inner tube 11, reflected by the adjacent injectors 62 and 66, reflected by the injector 64 in some cases, and then diffused in the Y2 direction toward the wafer W side. The various process gases discharged from the gas holes 64a are first reflected by the inner wall of the inner tube 11 and then reflected by the injector 64 and further to the adjacent injectors 62 and 66, so that the multi-reflected process gases diffuse not only in the horizontal direction but also in the vertical direction into the processing container 10.

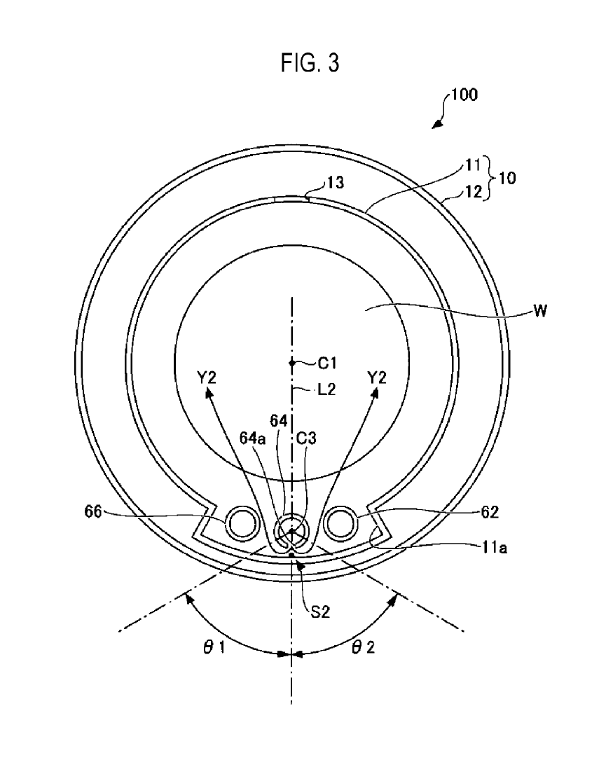

FIG. 3 is a sectional view taken along arrow in FIG. 1 and cut along a horizontal plane passing through a gas hole of the medium length injector (a plan view of the substrate processing apparatus). The injector 64 is installed in such a manner that the gas hole 64a is oriented within the same angular range as the gas hole 62a.

Further, in order to supply a process gas to the lower region of the inner tube 11, a plurality of gas holes 66a is opened and formed in the shortest injector 66 at predetermined intervals along the longitudinal direction within a predetermined range of the upper portion of the injector 66 and are oriented toward the inner wall side in the vicinity of the inner tube 11, such as the injectors 62 and 64. Then, various process gases discharged horizontally through the gas holes 66a oriented toward the inner wall side in the vicinity of the inner tube 11 can be first reflected by the inner wall surface and then supplied to the wafer W side in the Y3 direction. In addition, the various process gases discharged from the gas holes 66a of the injector 66 can be first reflected by the inner wall of the inner tube 11, reflected by the injector 66 and then diffused in the Y3 direction toward the wafer W side. Further, the various process gases discharged from the gas holes 66a of the injector 66 can be first reflected by the inner wall of the inner tube 11, reflected by the adjacent injector 64, additionally reflected by the injector 66 in some cases, and then diffused in the Y3 direction toward the wafer W side. The various process gases discharged from the gas holes 66a are first reflected by the inner wall of the inner tube 11 and then reflected by the injector 66 and further to the adjacent injector 64, so that the multi-reflected process gases diffuse not only in the horizontal direction but also in the vertical direction into the processing container 10.

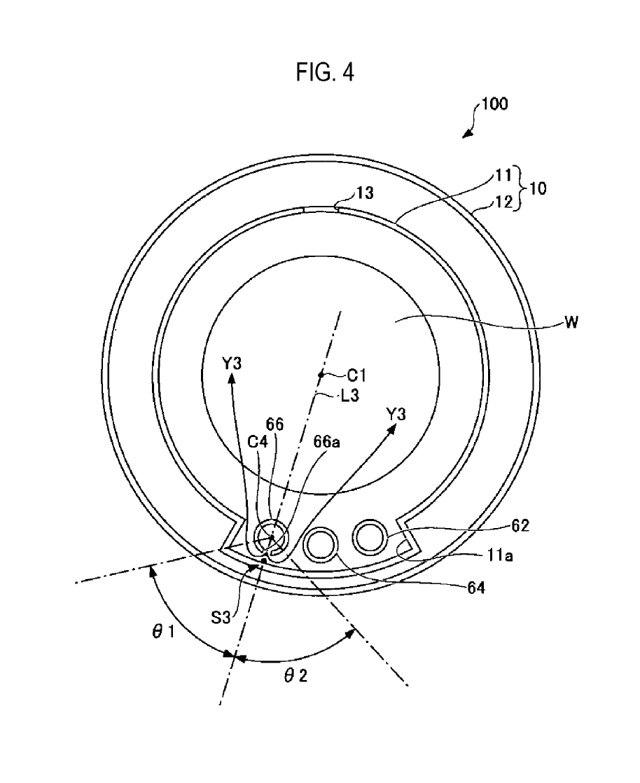

FIG. 4 is a sectional view taken along arrow IV-IV in FIG. 1 and cut along a horizontal plane passing through a gas hole of the shortest injector (a plan view of the substrate processing apparatus). The injector 66 is installed in such a manner that the gas hole 66a is oriented within the same angular range as the gas holes 62a and 64a.

The illustrated substrate processing apparatus 100 is a so-called side flow type substrate processing apparatus that supplies various process gases horizontally from the inner side of the inner tube 11 into the processing container 10. However, for example, this apparatus may be combined with an injector that supplies various process gases upwardly from the bottom of the inner tube 11. When the side flow type substrate processing apparatus is applied to supply a process gas to each wafer W, control is generally performed to rotate the wafer boat to supply the process gas onto the entire surface of each wafer W. However, in the illustrated substrate processing apparatus 100, even when the wafer boat 70 is not rotated, it is possible to supply the process gas uniformly onto the entire surface of the wafer W by a flow of the process gas reflected by the inner wall of the inner tube 11 and diffused toward the wafer W side.

In addition, unlike the illustrated substrate processing apparatus 100, a side flow type substrate processing apparatus having a plurality of injectors having the same length in the vertical direction may be adopted in which each injector has a plurality of gas holes which are capable of supplying the process gas from the lower end to the upper end of the wafer boat 70 and are spaced at predetermined intervals and the process gas is simultaneously supplied from the gas holes of the respective injectors. Further, a substrate processing apparatus having only one injector may be adopted. Further, a substrate processing apparatus having a single folded-type injector extending upward, folded back at the top and then extending downward may be adopted. Further, a substrate processing apparatus having a plurality of folded-type injectors having different heights may be adopted. In the case of a folded-type injector, after the precursor gas supplied from the downwardly extending region is reflected by the inner wall of the inner tube, the precursor gas is easily reflected in the adjacent upwardly extending region. Further, a control method in which the same process gas is supplied from a plurality of injectors for each process may be adopted. Further, a control method in which different kinds of process gases are supplied from different injectors in each process may be adopted in a controller having a plurality of injectors having the same length.

Examples of the process gases supplied from the respective gas holes 62a, 64a and 66a of the injectors 62, 64 and 66 may include various process gases such as a deposition gas (precursor gas), an etching gas, a purge gas, an oxidizing gas, a nitriding gas, and a reducing gas, which will be described in detail in the following description of a substrate processing method.

Returning to FIG. 1, a gas exhaust port 16 is formed above the side wall of the manifold 20, and communicates to a gas flow space 15 formed between the inner tube 11 and the outer tube 12. For example, a process gas supplied from the gas holes 62a of the injector 62 or the like is reflected by the inner wall of the inner tube 11, flows to the wafer W side, flows through the gas flow space 15 in the Y4 direction, flows into the gas exhaust port 16 in the Y5 direction and then is exhausted to the outside of the apparatus. The gas exhaust port 16 is provided with the gas exhaust part 90. The gas exhaust part 90 includes an exhaust flow path 92 communicating to the gas exhaust port 16, a vacuum pump 91 for executing vacuum suction of a process gas at the downstream end of the exhaust flow path 92, and a pressure regulating valve 93 for executing pressure regulation at the time of suction at an intermediate position of the exhaust flow path 92.

### <Controller>

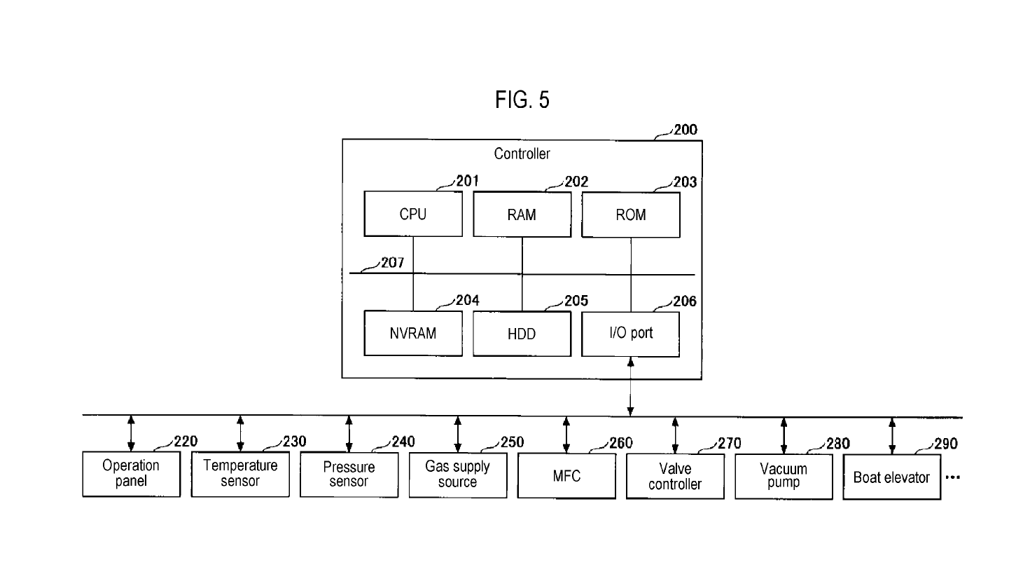

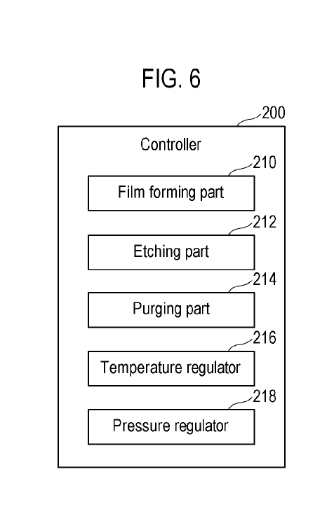

Next, a controller constituting the substrate processing system will be described. FIG. 5 is a view showing an exemplary embodiment of the hardware configuration of the controller. FIG. 6 is a view showing an exemplary embodiment of the functional configuration of the controller.

As shown in FIG. 5, the controller 200 includes a CPU (Central Processing Unit) 201, a RAM (Random Access Memory) 202, a ROM (Read Only Memory) 203, an NVRAM (Non-Volatile RAM) 204, an HDD (Hard Disk Drive) 205, an I/O port 206, and so on. The respective parts are communicably connected by a bus 207.

The ROM 203 stores various programs, data and so forth to be used by the programs. The RAM 202 is used as a storage area for loading a program or a work area for the loaded program. The CPU 201 implements various functions by processing the program loaded into the RAM 202. The HDD 205 stores programs, various kinds of data and so forth to be used by the programs. The NVRAM 204 stores various setting information and the like.

The HDD 205 stores various kinds of recipe information, for example, temperature conditions and pressure conditions for each process such as a film forming process, an etching process, a purging process, and sequence information related to process time. In addition, temperature and pressure changes in each region in the inner tube 11, start and stop timings of supply of a process gas, a supply amount of the process gas, and the like from loading of a predetermined number of wafers W into the substrate processing apparatus 100 to unloading of processed wafers W may be specified in detail in information stored in the HDD 205.

The I/O port 206 is connected to an operation panel 220, a temperature sensor 230, a pressure sensor 240, a gas supply source 250, an MFC (Mass Flow Controller) 260, a valve controller 270, a vacuum pump 280, a boat elevator drive mechanism 290 and so on and controls input/output of various data and signals.

The CPU 201 constitutes the center of the controller 200 and executes a control program stored in the ROM 203. Further, the CPU 201 controls the operation of respective parts constituting the substrate processing apparatus 100 according to a recipe (process recipe) stored in the HDD 205, based on an instruction signal from the operation panel 220. That is, the CPU 201 causes the temperature sensor (group) 230, the pressure sensor (group) 240, the gas supply source (group) 250, the MFC 260 and so on to measure the temperature, pressure, flow rate and the like of respective parts such as the interior of the inner processing tube 11 and the interior of the exhaust flow path 92. Then, based on the measurement data, the CPU 201 outputs control signals to the MFC 260, the valve controller 270, the vacuum pump 280, and controls these parts to conform to the process recipe.

As shown in FIG. 6, the controller 200 further includes a film forming part 210, an etching part 212, a purging part 214, a temperature regulator 216, a pressure regulator 218 and so on.

The film forming part 210 supplies various precursor gases to the surface of the wafer W to form a silicon film (Si film) made of amorphous silicon or the like or an insulating film of SiO₂, SiN or the like. Examples of a method of forming these Si film, insulating film and the like may include a CVD (Chemical Vapor Deposition) method, an ALD (Atomic Layer Deposition) method, an MLD (Molecular Layer Deposition) method and the like. In film formation by the film forming part 210, different silicon-containing gases (Si precursor gases) are sequentially supplied onto the wafer W according to the set process recipe, thereby sequentially forming silicon films.

For example, after a predetermined Si film is formed on the surface of the wafer W, the etching part 212 supplies an etching gas such as a halogen gas onto the wafer W to etch some or all of the Si film according to a process recipe.

The purging part 214 purges a supplied precursor gas, etching gas out of the processing container 10 according to a process recipe during the main processes such as the film forming process and the etching process or throughout the entire processes. The purging part 214 may supply an inert gas such as a nitrogen (N₂) gas into the processing container 10 throughout the entire processes except for the etching process and the film forming process.

The temperature regulator 216 regulates the internal temperature of the processing container 10, more precisely, the temperature of each of the wafers W placed in the wafer boat 70, to a temperature according to a process recipe for each of the various processes. For example, in the film forming process, when sequentially supplying different precursor gases to form a silicon film, the temperature regulator 216 regulates the internal temperature of the processing container 10 so that the wafer W has a temperature according to a process recipe for each precursor gas.

The pressure regulator 218 regulates the internal pressure of the processing container 10 to a certain pressure according to a process recipe for each of the various processes. For example, in the film forming process, when sequentially supplying different precursor gases to form a silicon film, the pressure regulator 218 regulates the internal pressure of the processing container 10 so that the interior of the processing container 10 has a pressure according to a process recipe for each precursor gas. In the purging process, in order to purge a precursor gas, an etching gas supplied into the processing container 10 in the preceding process within a predetermined time, a vacuum suction force of the vacuum pump 280 is adjusted by the pressure regulator 218.

### <Substrate Processing Method>

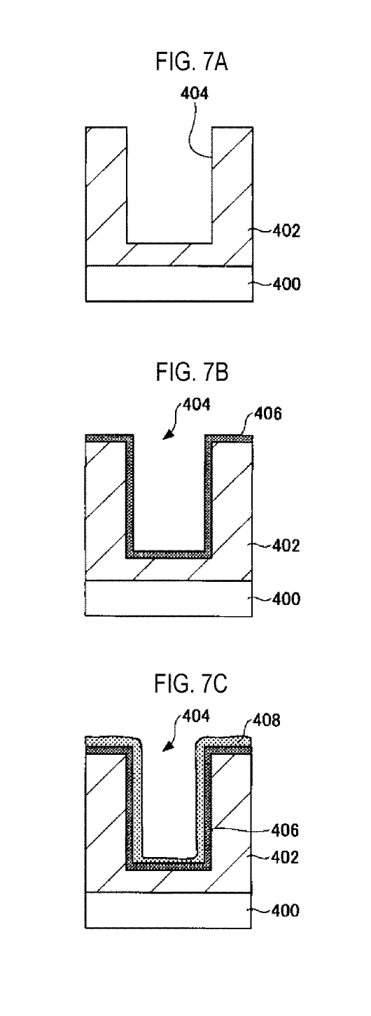

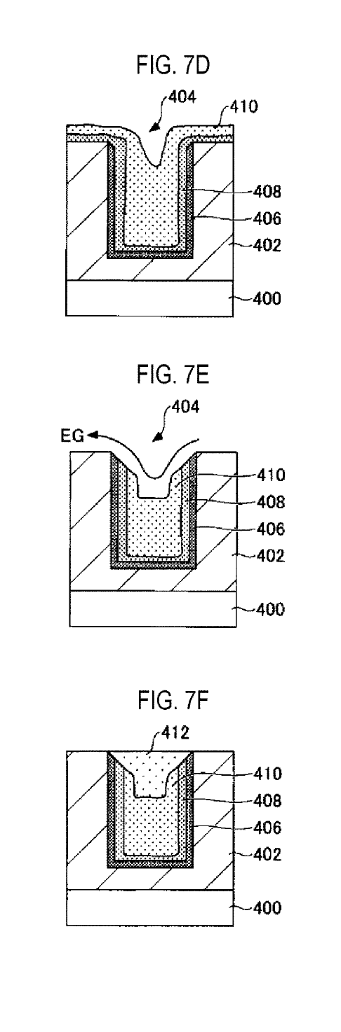

Next, a substrate processing method according to an embodiment of the present disclosure will be described. FIGS. 7A to 7F is a cross-sectional process view for explaining an example of a substrate processing method, showing a series of sequences from FIG. 7A to FIG. 7F.

First, as shown in FIG. 7A, a wafer 400 having an insulating film 402 formed of a SiO₂ film, a SiN film in which a recess 404 such as a trench or a hole is formed in a predetermined pattern is loaded into the processing container 10. As an example of the dimensions of the recess 404, an opening diameter or an opening width is 5 to 40 nm and a depth is about 50 to 300 nm.

Next, as shown in FIG. 7B, a first film forming step of supplying a first precursor gas into the processing container 10 is executed to form a first silicon film 406 (seed layer) made of amorphous silicon on the surface of the recess 404. The gas holes 62a, 64a and 66a of the respective injectors 62, 64 and 66 are oriented within the above-mentioned predetermined angular range, and the precursor gas discharged from each of the gas holes 62a, 64a and 66a is reflected by the inner wall of the inner tube 11 and is supplied onto each wafer W in the corresponding boat area.

Here, as the precursor gas for forming the first silicon film 406 made of amorphous silicon, it may be possible to use a silane-based compound or an aminosilane-based compound. Examples of the silane-based compound may include disilane (Si₂H₆). Examples of the aminosilane-based compound may include BAS (butylaminosilane), BTBAS (bis-tertiarybutylaminosilane), DMAS (dimethylaminosilane), BDMAS (bisdimethylaminosilane), DPAS (dipropylaminosilane), DIPAS (diisopropylaminosilane). In a case where the recess 404 is filled with an amorphous silicon film with a void as little as possible, it is preferable to form a so-called seed layer made of dimethylaminosilane, disilane on the surface of the recess 404.

Next, as shown in FIG. 7C, a second film forming step of supplying a second precursor gas into the processing container 10 is executed to form a second silicon film 408 (seed layer) made of amorphous silicon on the surface of the first silicon film 406. For example, after the first silicon film 406 is formed from dimethylaminosilane, the second silicon film can be formed from disilane. At the stage where the first silicon film 406 and the second silicon film 408 (the two seed layers) are formed in the recess 404, the recess 404 is not completely closed with the silicon films.

Therefore, in FIG. 7D, a third precursor gas is supplied onto the wafer 400 to form a third silicon film 410 which is thicker than the seed layers. For example, after the first silicon film 406 is formed from dimethylaminosilane and the second silicon film is formed from disilane, the third silicon film may be formed from monosilane (SiH₄). Here, as the process conditions in the film forming FIG. 7B to FIG. 7D, the internal temperature of the processing container 10 may be in a range of about 200 to 600 degrees C., and the internal pressure thereof may be in a range of 0.5 to 30 Torr (67 to 4,002 Pa).

Next, as shown in FIG. 7E, an etching gas EG formed of a halogen gas is supplied onto the wafer W to etch the first silicon film 406 to partially the third silicon film 410 (etching step). It may be possible to use, Cl₂, HCl, F₂, Br₂, or HBr, among which the Cl₂ gas or the HBr gas having good etching controllability is preferable, as the etching gas formed of the halogen gas. The gas holes 62a, 64a and 66a of the respective injectors 62, 64 and 66 are oriented within the above-mentioned predetermined angular range and, like the precursor gas, the etching gas discharged from each of the gas holes 62a, 64a and 66a is reflected by the inner wall of the inner tube 11 and is supplied onto each wafer W in the corresponding boat area. Here, as the process conditions in the etching step, the internal temperature of the processing container 10 may be in a range of about 200 to 500 degrees C., and the internal pressure thereof may be in a range of 0.1 to 10 Torr (13 to 1,334 Pa).

Next, as shown in FIG. 7F, in order to completely close the recess 404, the third precursor gas is again supplied onto the wafer 400 to form an additional third silicon film 412 on the third silicon film 410, thereby completely closing the recess 404 with the additional third silicon film 412.

According to the illustrated substrate processing method, various process gases are discharged from the gas holes 62a, 64a and 66a of the injectors 62, 64 and 66, reflected by the inner wall of the neighboring inner tube 11, and diffused into the processing container 10 to execute a film forming process, an etching process or the like on the wafer W. Therefore, it is possible to execute various processes sufficiently exhibiting actions by the various process gases. That is, in the film forming step, the film attachment is improved to shorten the incubation time as much as possible. In the etching step, good etching properties are obtained. In any of the processes, it is possible to execute an in-plane uniform film forming process or etching process on each wafer W and accordingly, it is possible to form a silicon film having good in-plane uniformity and inter-plane uniformity with respect to the film thickness on each wafer W.

### <Analysis and Results on Etching Gas Concentration in Wafer Surface and Experiment and Results on Etching Amount>

The present inventors modeled a substrate processing apparatus having the injectors shown in FIGS. 1 to 4 and a conventional substrate processing apparatus in a computer and analyzed the etching gas concentration in a wafer surface when an etching gas formed of a chlorine gas was used to execute an etching process on a wafer on which an amorphous silicon film was formed.

Experiments were also conducted on the etching amount in a wafer surface when an actual machine similar to the computer model was used to execute an etching process on a wafer on which an amorphous silicon film was formed.

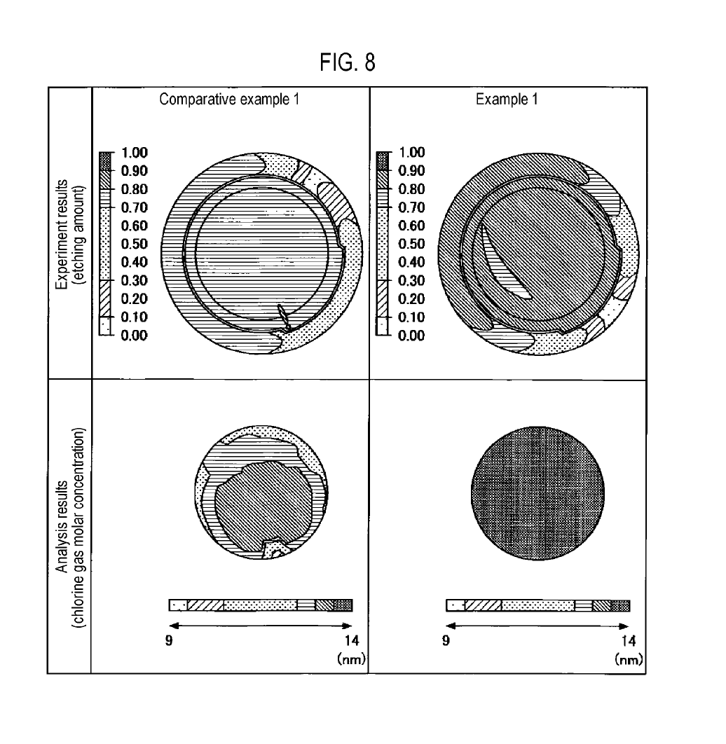

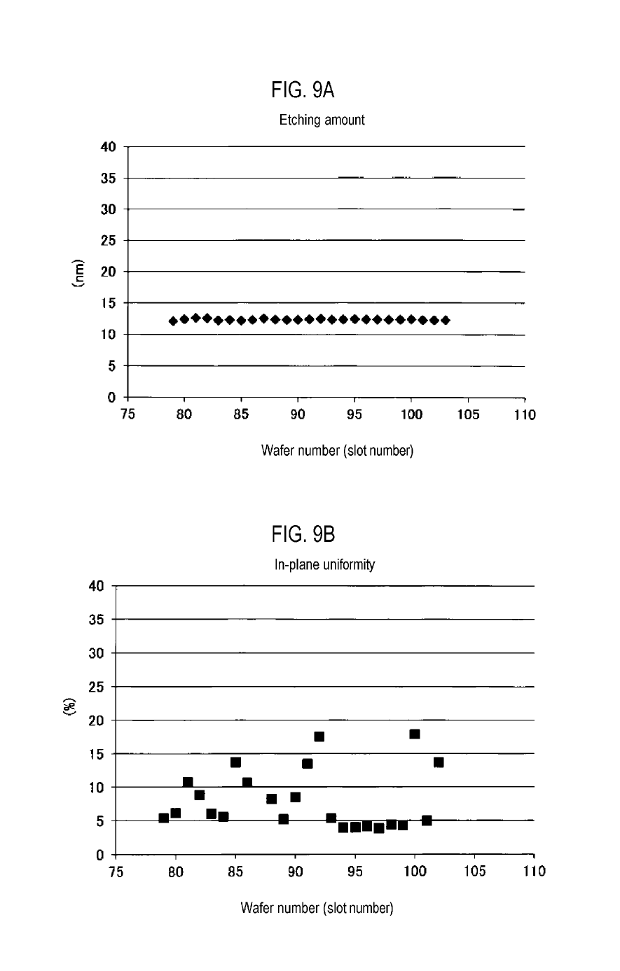

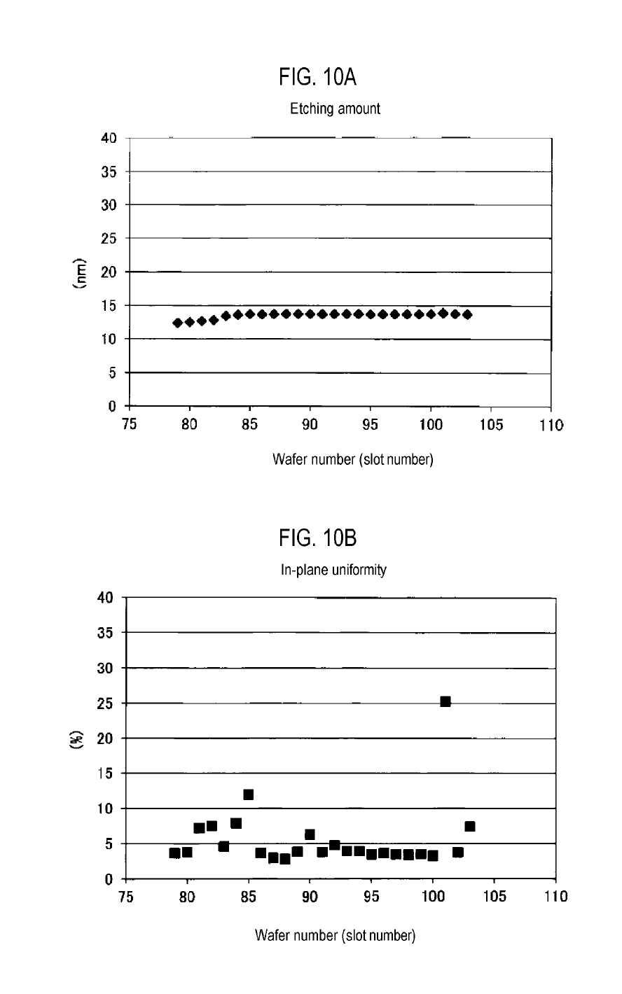

As the etching conditions, the internal temperature of the substrate processing apparatus was set to 350 degrees C., the internal pressure thereof was set to 0.3 Torr (40 Pa), and one injector (one system) was supplied with 1000 sccm of a chlorine gas for about 5 minutes. FIG. 8 is a view showing results of analysis on the etching gas concentration and results of experiments on the etching amount according to Comparative Example 1 in which an etching gas is provided in the wafer center direction and Example 1 in which the etching gas is provided in the tube direction (direction of 45 degrees counterclockwise from the reference points S1 to S3). The etching gas concentrations gradually converge to the same concentration over time, and the analysis results shown in FIG. 8 show states about 1.8 seconds after the start of supply of etching gas in order to clearly show the change in concentration in Comparative Example 1 and Example 1. FIG. 9A is a view showing the results of an experiment on the etching amount in Comparative Example 1 in the center area of the wafer boat, and FIG. 9B is a view showing the results of an experiment on in-plane uniformity in Comparative Example 1. FIG. 10A is a view showing the results of an experiment on the etching amount in Comparative Example 1 in the center area of the wafer boat, and FIG. 10B is a view showing the results of an experiment on in-plane uniformity in Example 1. In Comparative Example 1 and Example 1, the gas holes of the injector coincide with the wafer position only at the wafer number 92, but the gas holes of the injector do not coincide with the wafer position at other wafer numbers.

It can be seen from FIG. 8 that the chlorine gas concentration in Example 1 is higher throughout the entire wafer surface than in Comparative Example 1 in the results of analysis on the chlorine gas concentration.

Further, it has been demonstrated from the results of experiments on the etching amount that the etching amount in Example 1 is remarkably larger than that of Comparative Example 1 and is uniform in the wafer surface whereas the etching amount in Comparative Example 1 varies in the wafer surface. In addition, it has been confirmed that the range of etching in Example 1 is a range of about 1 nm in the wafer surface, showing good in-plane uniformity, whereas the range of etching in Comparative Example 1 is a range of 3.4 nm in the wafer surface.

Further, it can be seen from FIG. 9A that the etching amount in Comparative Example 1 is about 12 nm and it can be seen from FIG. 9B that the etching amount in Comparative Example 1 largely varies from 5 to 20% for each slot. It is considered that the reason for such large variation is that a singular point is generated in the in-plane uniformity in the vicinity of the wafer number 92. That is, it is inferred that, since the etching gas is supplied in the wafer center direction through gas holes formed at positions corresponding to the wafer number 92, the etching gas could not be decomposed sufficiently and accordingly could not react with the amorphous silicon film on the wafer surface.

In contrast, it can be seen from FIG. 10A that the etching amount in Example 1 is about 14 nm, which is higher by about 10 to 20% than the etching amount in Comparative Example 1 and it can be seen from FIG. 10B that the etching amount in Example 1 is collected around 5% in each slot, showing a small variation. It is inferred that the reason why the etching amount is increased is that the etching gas is heated and easily decomposed in the course of being reflected by the inner wall of the inner tube and being diffused. It is further inferred that the etching gas is supplied onto the entire wafer surface by being reflected and diffused by the inner wall of the inner tube, thereby reducing the variation.

It has been demonstrated from the results of this analysis and experiment that a silicon film having good in-plane uniformity can be formed on a wafer by applying the substrate processing apparatus and the substrate processing method according to the embodiment of the present disclosure.

<Experiment and Results on Film Thickness and in-Plane Uniformity>

The present inventors prepared a substrate processing apparatus according to Example 2 having the injectors shown in FIGS. 1 to 4 (having the gas hole orientation angle of 45 degrees from the reference point on the inner tube side) and a substrate processing apparatus according to Comparative Example 2 having the conventional injectors (having gas holes oriented in the wafer center direction). Subsequently, experiments were conducted to verify the film thickness of an amorphous silicon film formed when a boat on which about 200 wafers are mounted is accommodated in each substrate processing apparatus and a disilane gas as a precursor gas is supplied onto the wafers, and the uniformity of film thickness between wafers (inter-plane uniformity).

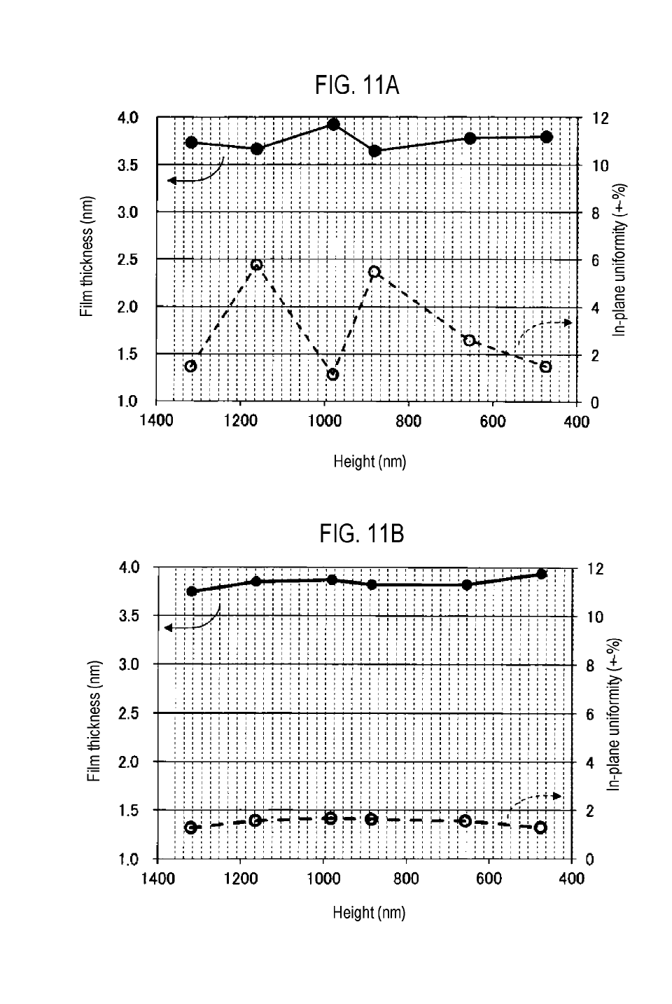

The substrate processing apparatus has three injectors (three systems), the interior of the substrate processing apparatus was set to a pressure atmosphere of 1.5 Torr (200 Pa), and 200 sccm of precursor gas was supplied from each injector. FIG. 11A is a view showing the results of an experiment on the film thickness and the in-plane film thickness uniformity in Comparative Example 2 ranging from the lower region to the upper region of the wafer boat, and FIG. 11B is a view showing the results of an experiment on the film thickness and the in-plane film thickness uniformity in Example 2 ranging from the lower region to the upper region of the wafer boat. In FIGS. 11A and 11B, the horizontal axis represents the height position from the upper surface of the lid 40, and the experiment results shown are those obtained by extracting the results of the height position range of 400 mm to 1,400 mm (region corresponding to the wafer boat). The gas holes of the injector coincide with the wafer position only at the heights of 1,880 mm and 880 mm, but do not completely coincide with the wafer position at the other heights.

It has been demonstrated from FIG. 11A that the film thickness varies in the height direction of the wafer boat and the inter-plane film thickness uniformity is about 6% maximum in Comparative Example 2. In contrast, it has been demonstrated from FIG. 11B that the film thickness varies little in the height direction of the wafer boat and the inter-plane film thickness uniformity is extremely small, such as less than 2%.

It has been demonstrated by these experiments that a silicon film having good in-plane uniformity can be formed on each of a plurality of wafers in a vertical batch furnace by applying the substrate processing apparatus and the substrate processing method according to the embodiment of the present disclosure.

### <Analysis and Results on Angular Range of Gas Hole of Injector>

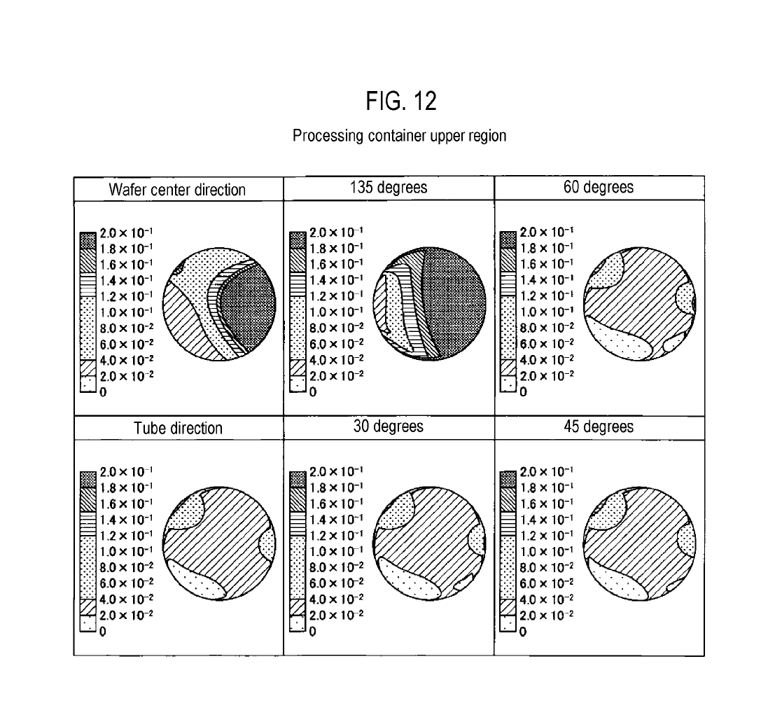

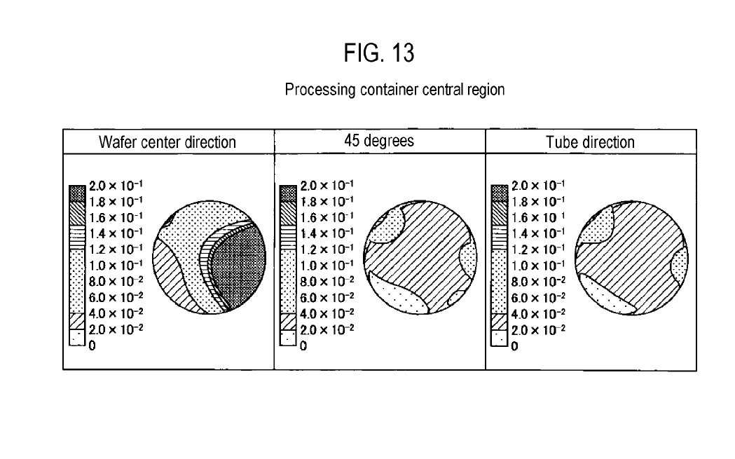

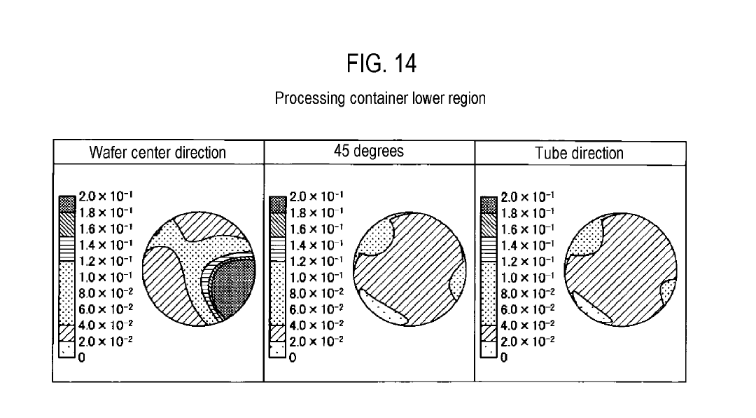

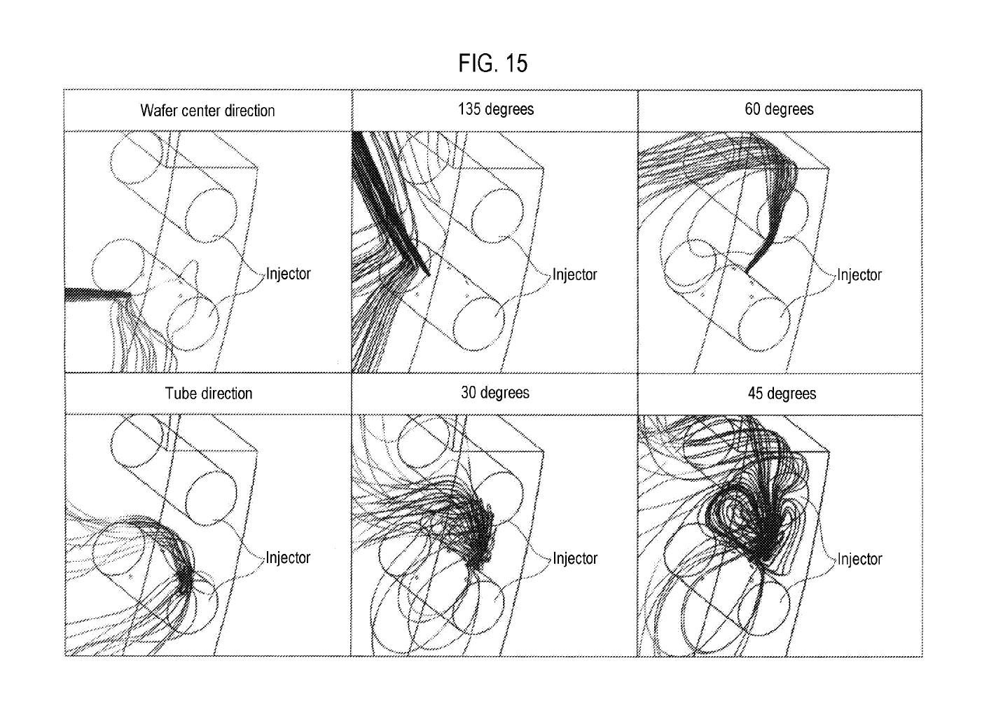

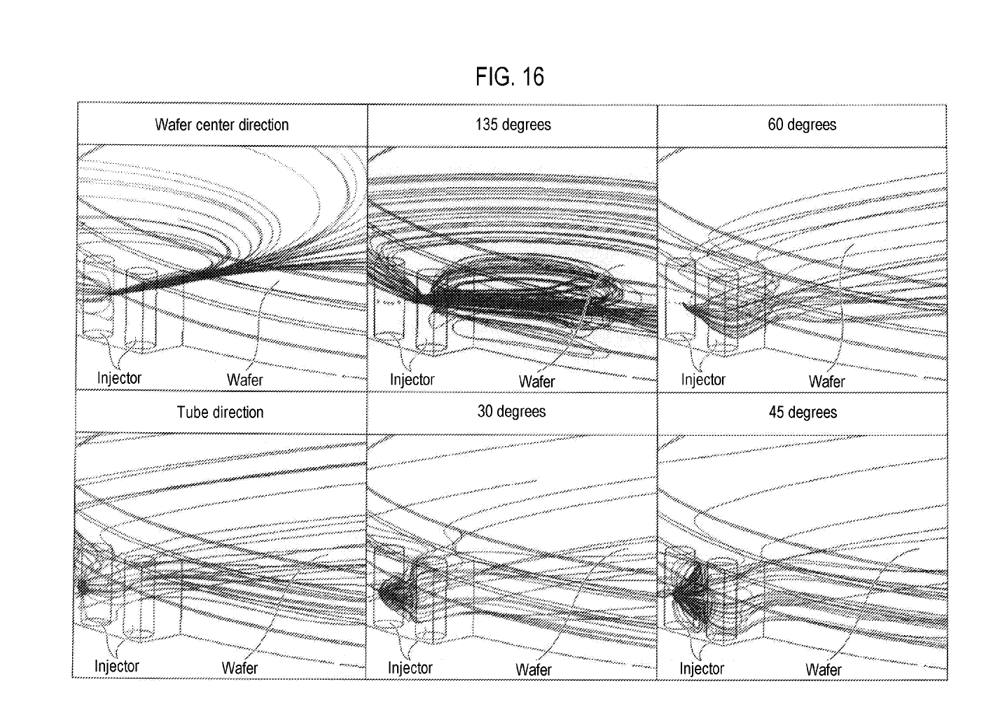

The present inventors conducted an analysis to define the angular range of the gas holes of the injector. In the analysis model, 156 wafers were mounted on the wafer boat at a predetermined interval in the vertical direction, and a process gas was supplied for every three wafers from one gas hole. The internal temperature of the processing container was set to 380 degrees C., the internal pressure thereof was set to 1.5 Torr (200 Pa), and 10 sccm of disilane gas as a precursor gas was supplied from each gas hole. FIGS. 12 to 14 are views showing the results of analysis on the airflow showing the flow velocity distribution of the precursor gas when the discharge direction of the precursor gas is changed, in the upper region, the central region and the lower region of the processing container, respectively. FIG. 15 is a view showing the results of analysis on airflow showing a streamline of the precursor gas in the vicinity of the injector. FIG. 16 is a view showing the results of analysis on airflow showing a streamline of the precursor gas from the injector to the wafer. For the upper region shown in FIG. 12, the results of the analysis in the tube direction (0 degree), 30 degrees, 45 degrees, 60 degrees, 135 degrees and wafer center direction in a counterclockwise manner around the tube direction (reference point direction) were obtained. For the central region and the lower region respectively shown in FIGS. 13 and 14, the analysis results for three directions, i.e., the wafer center direction, 45 degrees direction and tube direction were obtained.

It can be seen from FIG. 12 that, in the upper region, when the precursor gas is discharged in the wafer center direction and 135 degrees direction, the flow velocity distribution of the precursor gas becomes large and there is a large variation in the plane. In contrast, it can be seen that the flow velocity distribution of the precursor gas is extremely small in the other 60 degrees, 45 degrees, 30 degrees in the tube direction and there is a small variation in the plane.

It can be seen from FIGS. 13 and 14 that, when the precursor gas is discharged in the wafer center direction, the flow velocity distribution of the precursor gas becomes large and there is a large variation in the plane. In contrast, it can be seen that the flow velocity distribution of the precursor gas is extremely small in the 45 degrees direction and the tube direction and there is a small variation in the plane.

Further, it can be seen from FIGS. 12 to 14 that the flow rate of the precursor gas supplied onto the wafer is lower when supplied in the range of 60 degrees or less than the wafer center direction. As the flow velocity of the precursor gas decreases, the gas is easily heated and decomposed, thereby improving in-plane uniformity and inter-plane uniformity.

Further, it can be seen from FIGS. 15 and 16 that, when the precursor gas is supplied in the wafer center direction, there is almost no diffusion of the precursor gas in the vertical direction, and the precursor gas flows toward one wafer. In contrast, it can be seen that, when the precursor gas is supplied in the range of 60 degrees or less, the precursor gas is reflected by the inner wall of the inner tube, reflected by the adjacent injector and then diffused in the vertical direction. Alternatively, it can be seen that, the precursor gas is reflected by the inner wall of the inner tube, reflected by the adjacent injector, further reflected to the injector itself which supplied the precursor gas, and then diffused in the vertical direction. In addition, it can be seen that, when the precursor gas is supplied in the tube direction (0 degrees), the precursor gas is reflected by the inner wall of the inner tube, reflected to the injector itself which supplied the precursor gas, and then diffused in the vertical direction.

As can be understood from these analysis results, the angular range of the gas hole of the injector, that is, an angular range from the reference point around the axial center of the injector when a point where the radial line passing through the center of the wafer mounted on the boat and the center of the injector intersects the inner wall is the reference point, is preferably the angular range of 60 degrees or less in both clockwise and counterclockwise directions. Particularly, when the precursor gas is reflected by the inner wall of the inner tube and then reflected and diffused by the adjacent injector, the angle of the gas hole is preferably in the above-mentioned angle range of 60 degrees or less at which the precursor gas can reliably be reflected by the inner wall of the inner tube, more preferably in an angular range of 45 degrees or less at which the precursor gas can be more strongly reflected, although the gas hole angle is set according to the distance to the adjacent injector.

Other embodiments in which other constituent elements are combined with those described in the above embodiments may be used, and the present disclosure is not limited to the configurations described here. This point can be changed without departing from the spirit and scope of the present disclosure and can be appropriately determined according to the form of applications.

According to the substrate processing apparatus and the substrate processing method according to some embodiments of the present disclosure, it is possible to form a silicon film having good in-plane uniformity and inter-plane uniformity on a substrate.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a processing container accommodating a boat on which a substrate is mounted; and
an injector that extends in a vertical direction along an inner wall of the processing container in a vicinity of the processing container and has a plurality of gas holes in a longitudinal direction,
wherein the plurality of gas holes is oriented toward the inner wall in the vicinity of the processing container.

2. The substrate processing apparatus of claim 1, wherein the plurality of gas holes is oriented in an angular range of 60 degrees or less in each of clockwise and counterclockwise directions, which corresponds to the angular range around an axial center of the injector from a reference point, and
wherein the reference point is a point where a radial line passing through the center of the substrate mounted on the boat and the center of the injector intersects the inner wall in a plan view of the substrate processing apparatus.

3. The substrate processing apparatus of claim 2, wherein the angular range is an angular range of 45 degrees or less in each of the clockwise and counterclockwise directions.

4. The substrate processing apparatus of claim 1, wherein a process gas supplied into the processing container from the plurality of gas holes of the injector is reflected by the inner wall and then diffused into the processing container.

5. The substrate processing apparatus of claim 1, wherein the injector is one of a plurality of injectors having different lengths in the longitudinal direction, one of a plurality of injectors having the same length in the longitudinal direction, or one of a single or plurality of folded type injectors extending in an upward direction, being folded back at the top and then extending in a downward direction, the plurality of folded type injectors having different heights.

6. The substrate processing apparatus of claim 5, wherein a process gas supplied from the plurality of gas holes of the injector into the processing container is reflected by the inner wall, reflected by the adjacent injector and then diffused into the processing container.

7. The substrate processing apparatus of claim 1, wherein a process gas supplied from the plurality of gas holes of the injector into the processing container is reflected by the inner wall, reflected by the injector itself and then diffused into the processing container.

8. The substrate processing apparatus of claim 1, wherein a process gas supplied from the plurality of gas holes into the processing container is a precursor gas for film formation.

9. The substrate processing apparatus of claim 1, wherein a process gas supplied from the plurality of gas holes into the processing container is an etching gas.

10. A method of processing a substrate in a processing container in which a boat on which the substrate is mounted is accommodated, the method comprising:
supplying a process gas from a plurality of gas holes of an injector that extends in a vertical direction along an inner wall of the processing container in a vicinity of the processing container,
wherein the process gas is discharged toward the inner wall in a vicinity of the injector from the plurality of gas holes of the injector, reflected by the inner wall, and then diffused into the processing container to process the substrate.

11. The method of claim 10, wherein the injector is one of a plurality of injectors having different lengths in a longitudinal direction, one of a plurality of injectors having the same length in the longitudinal direction, or one of a single or plurality of folded type injectors extending in an upward direction, being folded back at the top and then extending in a downward direction, the plurality of folded type injectors having different heights, and
wherein the process gas is discharged toward the inner wall in the vicinity of the injector from the plurality of gas holes of the injector, reflected by the inner wall, reflected by the adjacent injector, and then diffused into the processing container to process the substrate.

12. The method of claim 10, wherein the process gas is discharged toward the inner wall in the vicinity of the injector from the plurality of gas holes of the injector, reflected by the inner wall, reflected by the injector itself, and then diffused into the processing container to process the substrate.

13. The method of claim 10, wherein the process gas is discharged in an angular range of 60 degrees or less in each of clockwise and counterclockwise directions, which corresponds to the angular range around an axial center of the injector from a reference point, and
wherein the reference point is a point where a radial line passing through the center of the substrate mounted on the boat and the center of the injector intersects the inner wall in a plan view of the processing container.

14. The method of claim 13, wherein the angular range is an angular range of 45 degrees or less in each of the clockwise and counterclockwise directions.

15. The method of claim 10, wherein the process gas supplied from the plurality of gas holes into the processing container is a precursor gas for film formation.

16. The method of claim 10, wherein the process gas supplied from the plurality of gas holes into the processing container is an etching gas.
